(19) United States
(12) Patent Application Publication
(10) Pub. No.: US 2014/0061906 A1
(43) Pub. Date: Mar. 6, 2014

(54) SEMICONDUCTOR STRUCTURE

(71) Applicant: CHIPMOS TECHNOLOGIES INC., Hsinchu (TW)

(72) Inventor: TSUNG JEN LIAO, HSINCHU (TW)

(73) Assignee: CHIPMOS TECHNOLOGIES INC., Hsinchu (TW)

(21) Appl. No.: 13/867,876

(22) Filed: Apr. 22, 2013

(30) Foreign Application Priority Data
Aug. 31, 2012 (TW) 101131682

(51) Int. Cl. H01L 23/00

(52) U.S. Cl. CPC H01L 24/13
USPC 257/738

(57) ABSTRACT

A semiconductor structure includes a semiconductor substrate, a metal layer formed on the semiconductor substrate, a conductive pillar, and a solder ball. The conductive pillar is formed on and electrically connected with the metal layer, wherein the conductive pillar has a bearing surface and a horizontal sectional surface under the bearing surface, and the contact surface area of the bearing surface is larger than the area of the horizontal sectional surface. The solder ball is located on the conductive pillar and covers the bearing surface.

### BACKGROUND

1. Technical Field

The present invention generally relates to a semiconductor structure, and more particularly, the improvement of the bondability between a solder ball and an element it adheres to.

2. Related Art

As semiconductor technology changes, the electronic engineering goes from thick film to thin film and to a more minimized scale of the devices. Semiconductor packaging itself is a process of making connection between different devices to form electrical circuits; therefore, to keep up with the rapidly changed semiconductor technology, packaging technique must also advance.

In semiconductor packaging, the connection between solder balls and chips or other components needs to meet certain reliability to avoid electrical malfunction or breakdown after packaging. In most situations, solder balls are adhered to the bond pads or conductive pillars on a chip. However, practically, peeling off or ineffective adherence of the solder balls is likely to occur, leading to a reduction in production yield.

Therefore, a method to increase the bondability between solder balls and chips so as to ensure the reliability is described in further detail.

### SUMMARY

In one embodiment of the present invention, a semiconductor structure includes a semiconductor substrate; a metal layer formed on the semiconductor substrate; a conductive pillar formed on the metal layer and electrically coupled with the metal layer. The conductive pillar includes a bearing surface and a horizontal cross-sectional surface under the bearing surface. A solder ball is placed on the conductive pillar. The contact surface area of the bearing surface is larger than the area of the horizontal cross-sectional surface.

In one embodiment of the present invention, the bearing surface is not a horizontal plane and includes a protrusion located in the center.

In one embodiment of the present invention, the bearing surface is not a horizontal plane but a concave surface.

In one embodiment of the present invention, the bearing surface is not a horizontal plane and includes a wall and a concave region, wherein the wall surrounds the concave region.

In one embodiment of the present invention, the metal layer is an under bump metallization (UBM).

To provide a better understanding of the characteristics and advantages of the present invention, a detailed explanation is provided in the following embodiments with reference to the drawings.

### BRIEF DESCRIPTION OF THE DRAWINGS

The invention will be described according to the appended drawings in which:

FIGS. 1A and 1B show a semiconductor structure with a bearing surface of the conductive pillar comprising a protrusion according to one embodiment of the present invention;

FIGS. 2A-2D show the manufacturing processes of fabricating a semiconductor structure with a bearing surface of the conductive pillar comprising a protrusion according to one embodiment of the present invention;

FIG. 3 shows a semiconductor structure with a bearing surface of the conductive pillar comprising a protrusion according to one embodiment of the present invention;

FIG. 4 shows a semiconductor structure with a concave bearing surface of the conductive pillar according to one embodiment of the present invention;

FIG. 5 shows a semiconductor structure with a bearing surface of the conductive pillar comprising a concave region according to one embodiment of the present invention;

FIG. 6 shows a semiconductor structure with a bearing surface of the conductive pillar comprising a plurality of protrusions according to one embodiment of the present invention; and

FIGS. 7 and 8 show the semiconductor structures having solder balls placed on the bearing surfaces of the conductive pillars according to the embodiments of the present invention.

### DESCRIPTION OF THE EMBODIMENTS

The following detailed description states the instructions or methods of the present invention. The detailed descriptions should not limit the present invention. It should also be realized that any equivalent functions or devices do not depart from the spirit and scope of the invention as set forth in the appended claims.

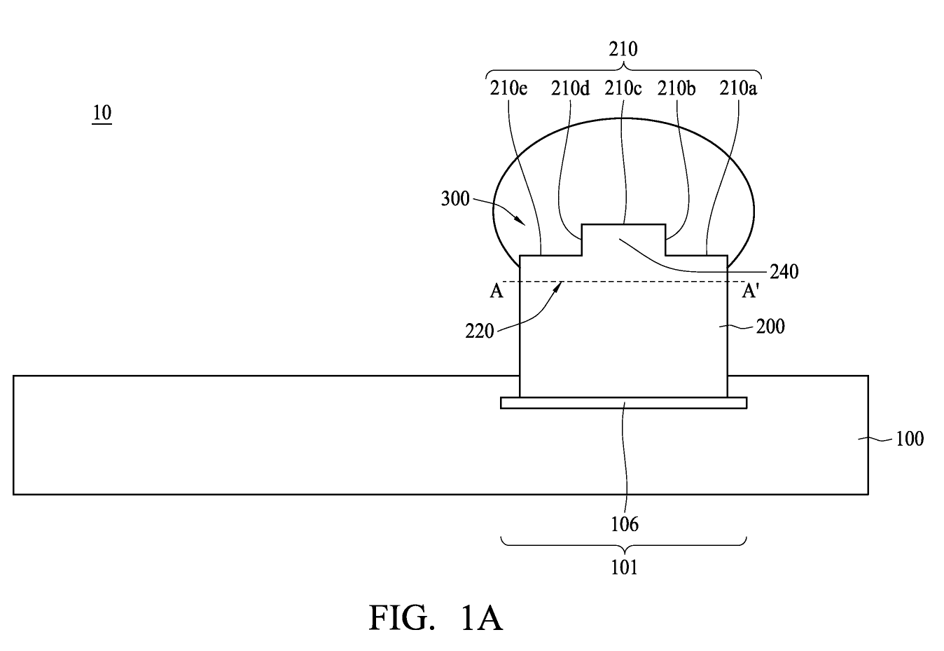

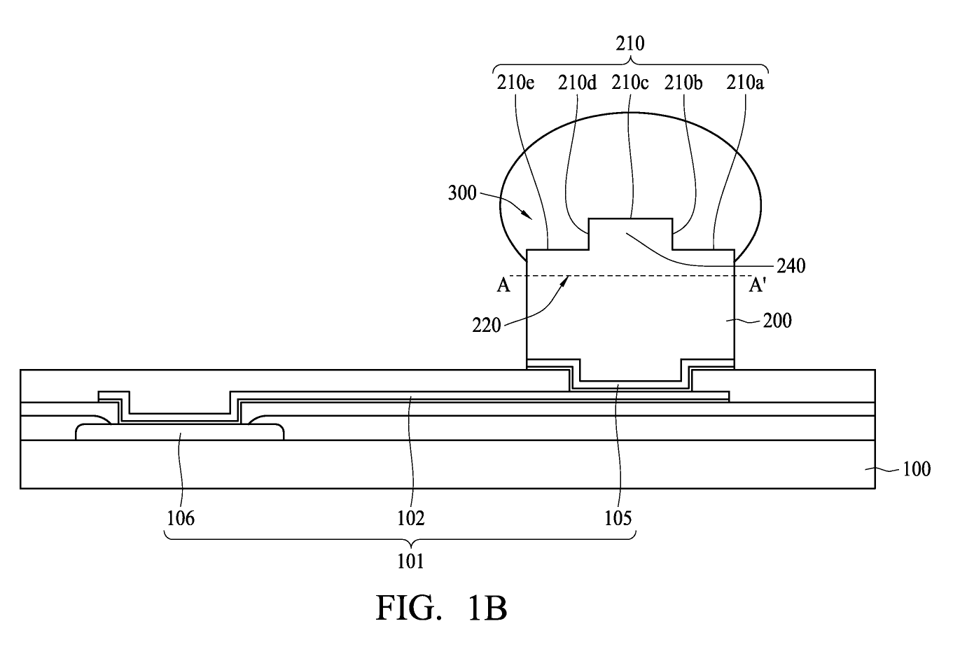

FIG. 1 is an embodiment of the present invention, showing a semiconductor structure 10. The semiconductor structure 10 includes a semiconductor substrate 100, which may be a semiconductor wafer or a chip. The semiconductor structure 10 also includes a metal layer 101 formed on the semiconductor substrate 100, where the metal layer 101 may be a bond pad 106 of a semiconductor wafer or a chip, an under bump metallization (UBM), a redistribution layer (RDL), or a layer including a bond pad 106, an UBM 105 and a RDL 102 as shown in FIG. 1B. In this description, they are generally called metal layers, and the main function of the metal layers is to provide the route for electrical currents. A conductive pillar 200 is formed on the metal layer 101 and coupled with the metal layer 101. The conductive pillar 200 has a bearing surface 210 for other elements such as a solder ball 300 to be adhered thereon as shown in FIG. 1A. In this embodiment, the bearing surface 210 is not a horizontal plane, as shown in FIG. 1, wherein a protrusion 240 lies in the center of the plane. The total surface area or so-called the contact surface area is the sum of the surfaces 210a˜210e. A horizontal cross-sectional surface 220 of the conductive pillar 200 is further defined herein as being under the bearing surface 210. As shown in FIG. 1A the horizontal cross-sectional surface 220 is a cross-section taken along line AA′. Since the contact surface area of the bearing surface 210 is larger than the area of the horizontal cross-sectional surface 220, thus the increased contact area between the solder ball 300 and the conductive pillar 200 can improve the adherence in comparison with a horizontal bearing surface. After applying a thermal process such as reflow or laser heating, the solder ball 300 then covers the bearing surface 200 of the conductive pillar 200. The method of placing the solder ball 300 on the conductive pillar 200 may be selected from but not limited to screen printing, vapor deposition, electroplating, ball drop, or ball spray.

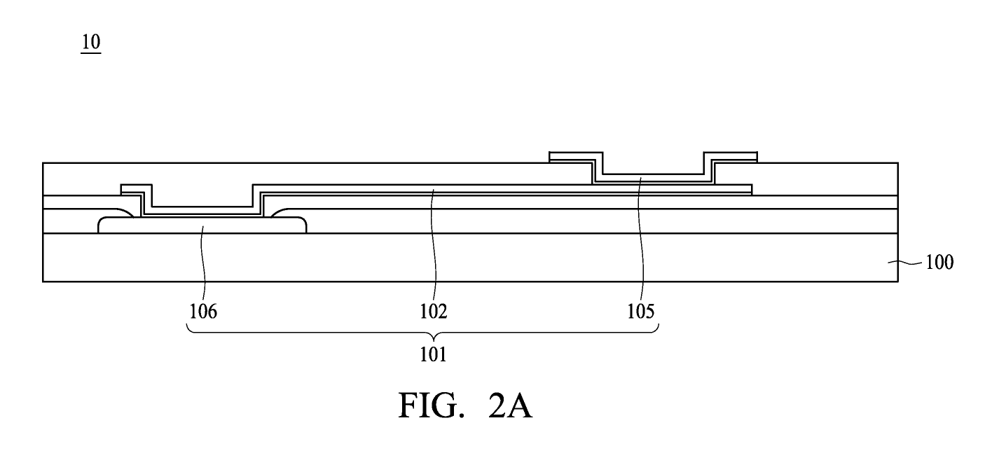

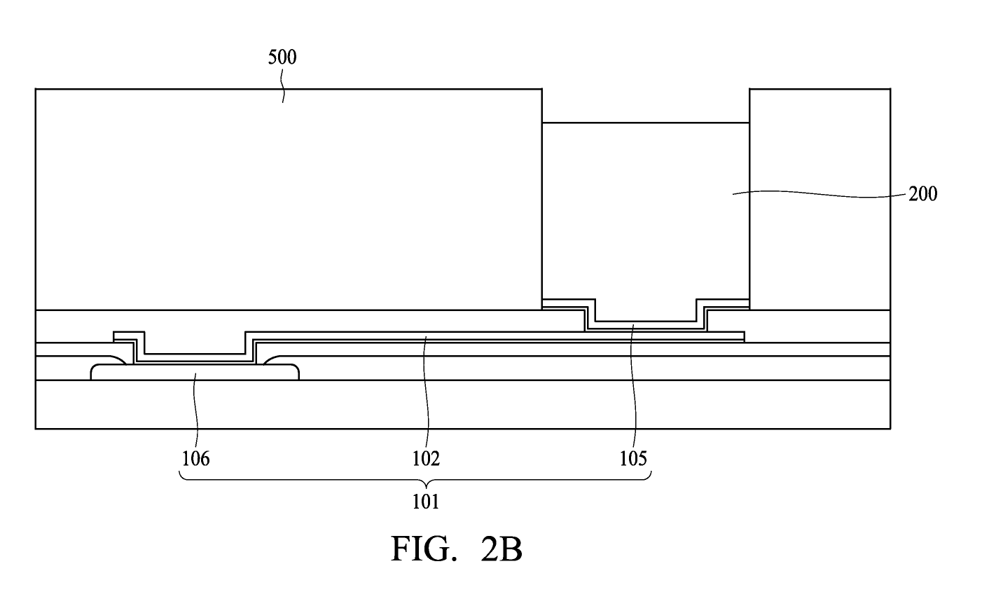

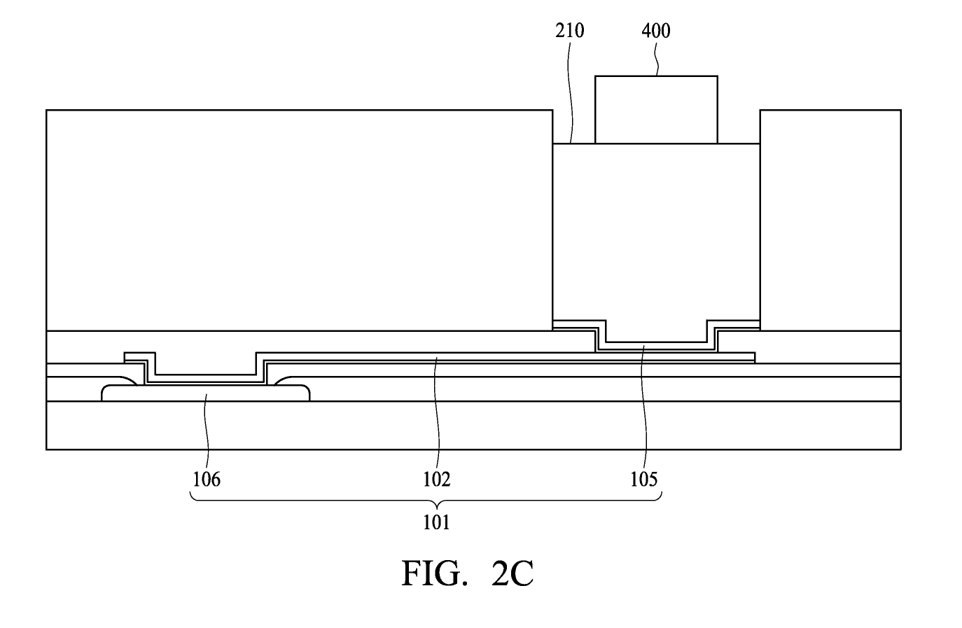

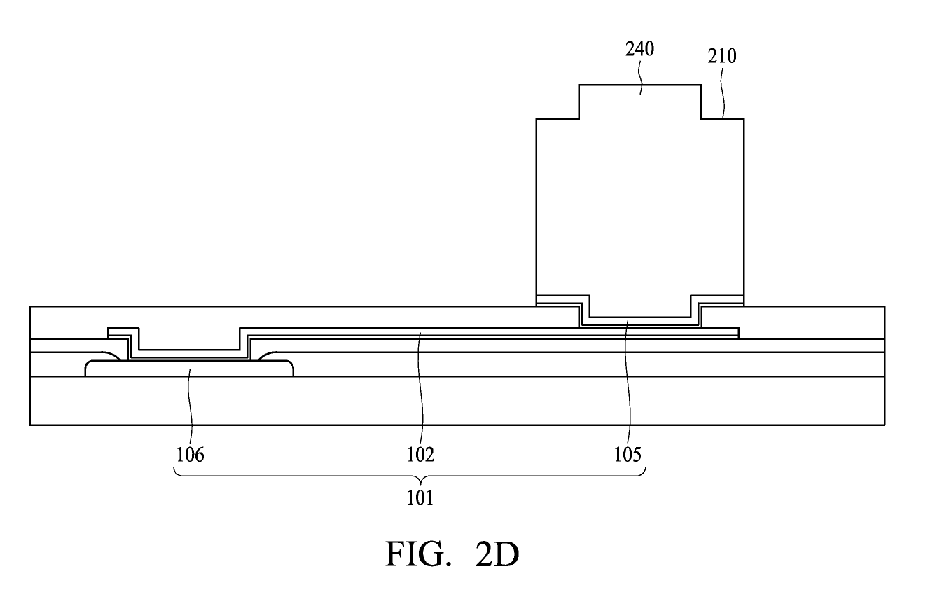

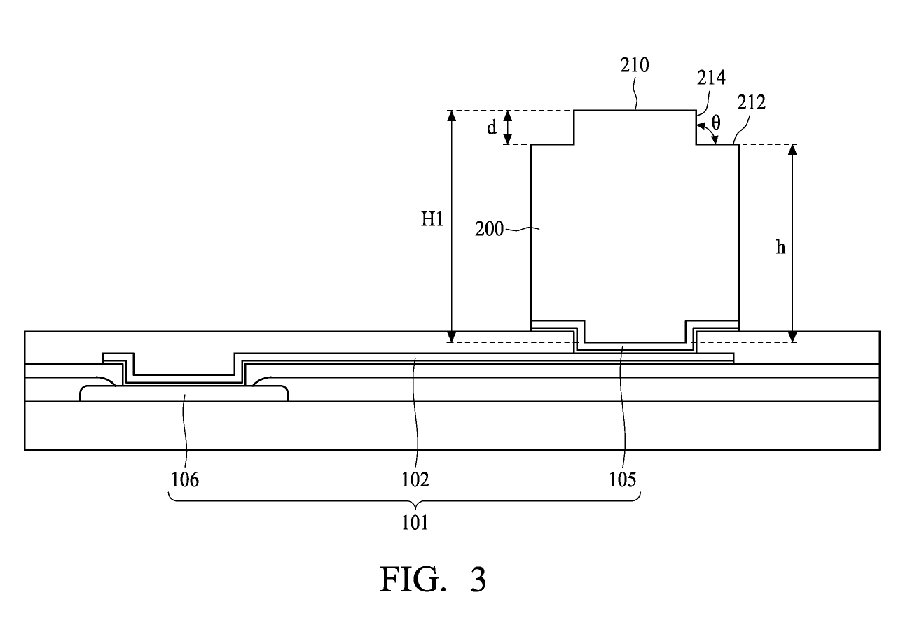

FIGS. 2A-2D show a process of fabricating the semiconductor structure 10. First, a semiconductor substrate 100 is provided, wherein the semiconductor substrate 100 includes the metal layer 101. Then, as shown in FIG. 2B, a patterned mask 500 is formed of a insulating material such as photoresist or dry film on the semiconductor substrate 100, and a conductive pillar 200 is then formed on the metal layer 101 by electroplating, for example, according to the patterned mask 500. The material of the conductive pillar 200 may be any kind of conductive material, for instance, a copper pillar in the present embodiment. FIG. 2C depicts the step of coating a photoresist 400 on a predetermined region of the bearing surface 200 of the conductive pillar 200, followed by etching out the region uncovered by the photoresist 400 to a thickness d as shown in FIG. 3. After the photoresist 400 is removed, the bearing surface 210 having a protrusion 240, shown in FIG. 2D, is formed. The total surface area of the bearing surface 210 with the protrusion 240 is larger than the surface area of a horizontal plane.

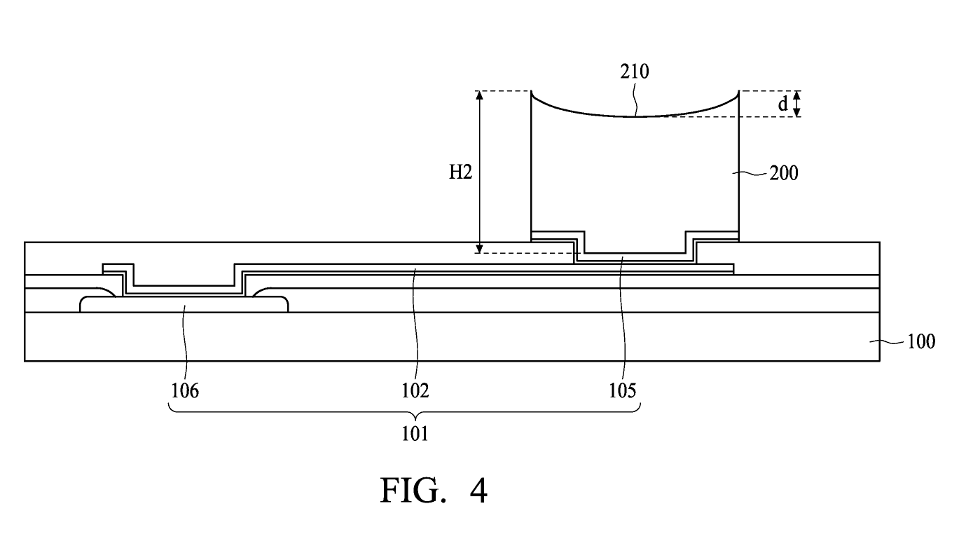

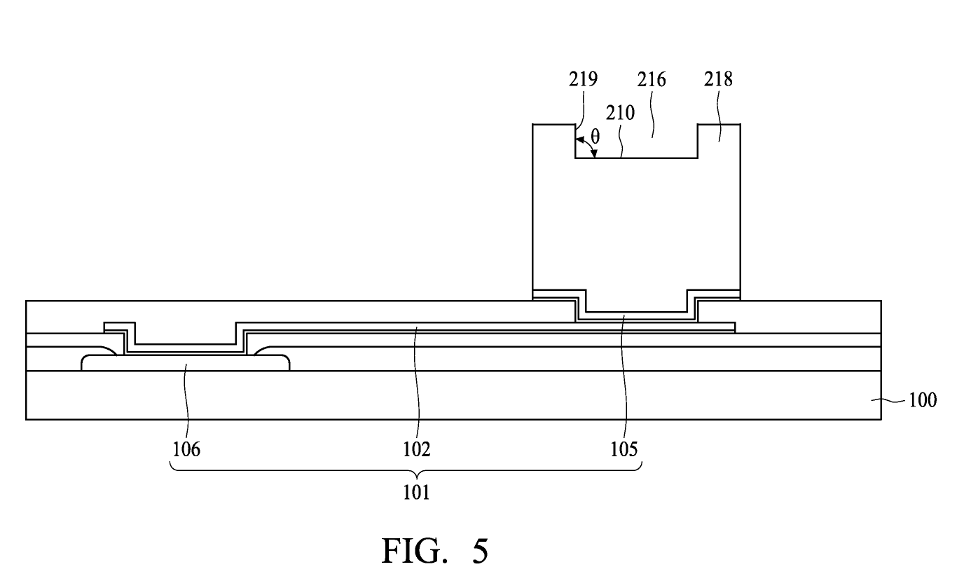

In another embodiment of the present invention, after a patterned mask 500 is formed on the semiconductor substrate 100 and a conductive pillar 200 is formed on the metal layer 101 as shown in FIG. 2B, a wet etching is directly applied on the bearing surface 210 to form a concave surface. Once the patterned mask 500 is removed, the conductive pillar 200 with a concave bearing surface 210 is then formed as shown in FIG. 4. Similarly, in another embodiment of the present invention, after a patterned mask 500 is formed on the semiconductor substrate 100 and a conductive pillar 200 is formed on the metal layer 101 as shown in FIG. 2B, a laser carving is applied directly on the bearing surface 210 so that after the patterned mask 500 is removed, the bearing surface 210 having a protrusion 240 as shown in FIG. 2D is then formed, or the bearing surface 210 having a wall 218 and a concave region 216 as shown in FIG. 5 is then formed.

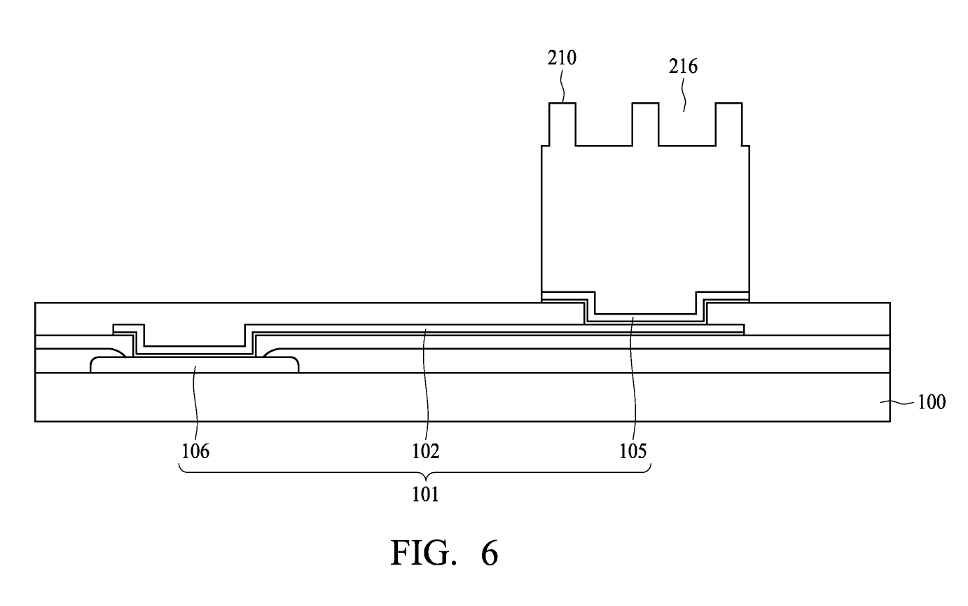

Moreover, during the process of forming the bearing surface 210, the total surface area of the bearing surface 210 may be changed by the combination of etching and laser carving, as shown in FIG. 6, so that a plurality of protrusions 240 or concave regions 216 can be formed on the bearing surface 210. By this way, the contact surface area of the bearing surface 210 can be adjusted as per requirements. Other shapes of the bearing surface 210 could also be achieved by the combination of dry etch, wet etch, and laser etching processes.

In the present invention, the contact surface area of the bearing surface 210 could be changed by a process adjustment. In reference to FIG. 1A and FIG. 1B, in one embodiment, the contact surface area of the bearing surface 210 is larger than or equal to 1.2 times the area of the horizontal cross-sectional surface 220. In another embodiment, the contact surface area of the bearing surface 210 is between 1.2 and 1.6 times larger than the area of the horizontal cross-sectional surface 220. In another embodiment, the contact surface area of the bearing surface 210 is between 1.2 and 2 times larger than the area of the horizontal cross-sectional surface 220. In another embodiment, the contact surface area of the bearing surface 210 is between 1.5 and 2 times larger than the area of the horizontal cross-sectional surface 220. In another embodiment, the contact surface area of the bearing surface 210 is between 1.5 and 2.5 times larger than the area of the horizontal cross-sectional surface 220. In another embodiment, the contact surface area of the bearing surface 210 is between 1.5 and 3 times larger than the area of the horizontal cross-sectional surface 220. In another embodiment, the contact surface area of the bearing surface 210 is between 2 and 2.5 times larger than the area of the horizontal cross-sectional surface 220. In yet another embodiment, the contact surface area of the bearing surface 210 is between 2 and 3 times larger than the area of the horizontal cross-sectional surface 220.

According to an embodiment of the present invention, shown in FIG. 3, the semiconductor structure 10 has a pillar height H1 measured from the highest point of the bearing surface 210 to the surface of the metal layer 101 and a lowest point height h measured from the lowest point of the bearing surface 210 to the surface of the metal layer 101, wherein the lowest point height h is between 70% and 95% of the pillar height H1. In another embodiment, the lowest point height h is between 65% and 95% of the pillar height H1. In another embodiment, the lowest point height h is between 80% and 95% of the pillar height H1. In another embodiment, the lowest point height h is between 85% and 95% of the pillar height H1. In yet another embodiment, the lowest point height h is between 70% and 85% of the pillar height H1.

Referring to FIG. 3 and FIG. 4, the conductive pillar 200 includes a pillar height H1 or H2 measured from the highest point of the bearing surface 210 to the surface of the metal layer 101, and a distance d between the highest point of the bearing surface 210 to the lowest point of the bearing surface 210 is between 5% and 15% of the pillar height H1 or H2. In another embodiment, the distance d is between 5% and 7% of the pillar height H1 or H2. In another embodiment, the distance d is between 7% and 10% of the pillar height H1 or H2. In another embodiment, the distance d is between 10% and 13% of the pillar height H1 or H2. In another embodiment, the distance d is between 13% and 15% of the pillar height H1 or H2. In yet another embodiment, the distance d is between 8% and 13% of the pillar height H1 or H2.

Referring to FIG. 3, the bearing surface 210 includes a first plane 212 surrounding the protrusion 240, and the protrusion 240 includes a sidewall 214, wherein the angle included by the sidewall 214 and the first plane 212 is between 70 and 90 degrees.

Referring to FIG. 5, the wall 218 includes an inner sidewall 219, and the angle included by the inner sidewall 219 and a surface of the concave region 216 is between 70 and 90 degrees.

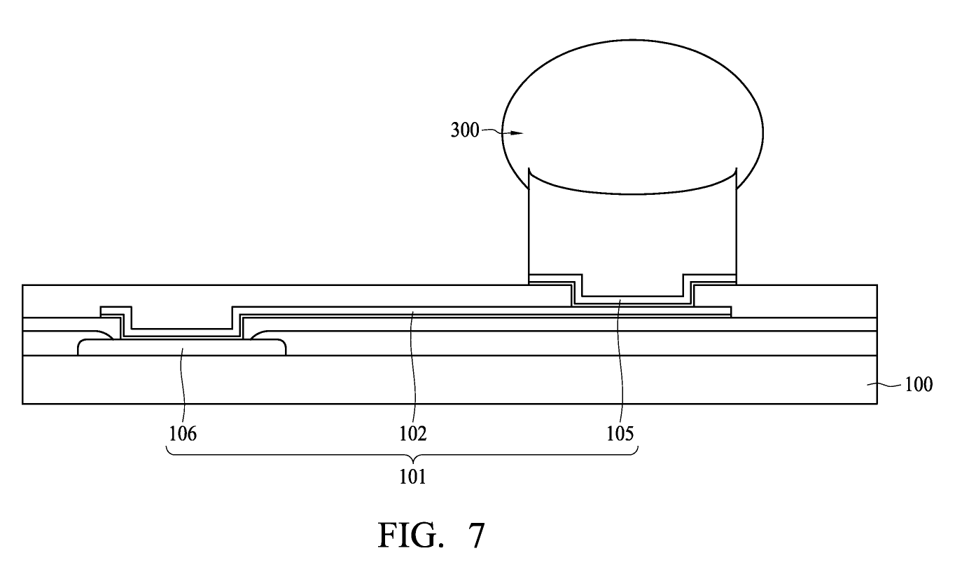

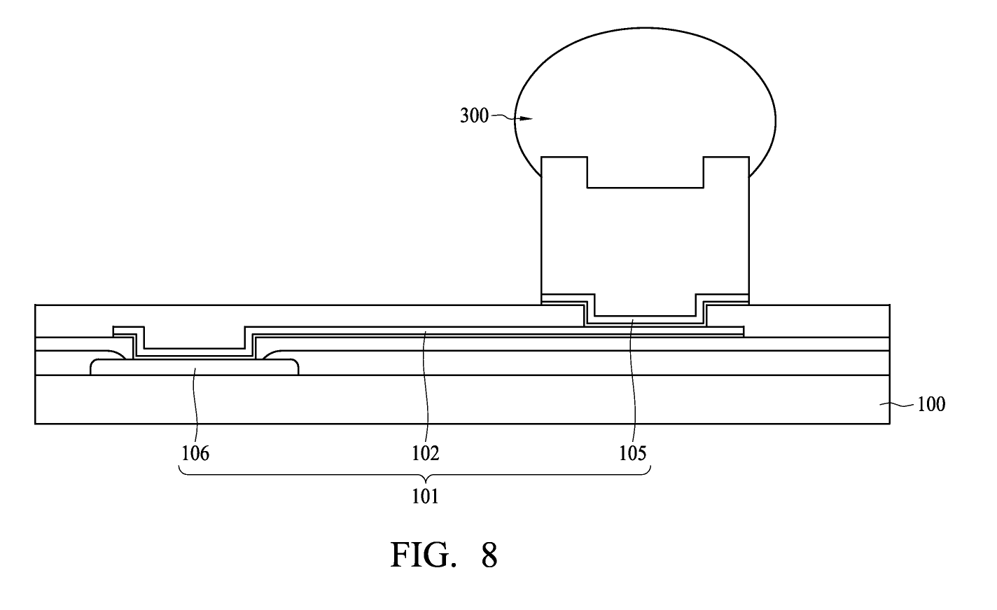

FIGS. 7 and 8 show an embodiment in which the solder ball 300 is placed on the bearing surface 210. In any embodiment of the present invention, a larger contact area between the solder ball 300 and the bearing surface 210 of the conductive pillar 200 may be obtained; hence, the bondability between the solder ball 300 and the conductive pillar 200 can be enhanced as well as the reliability of the semiconductor structure.

Although the technique content and characteristics of the invention have been described herein, many modifications and addictions may be made by those skilled in the relevant art within the scope of the invention. Therefore, it will be apparent that the invention is not limited thereto, and many modifications and addictions will be covered by the following claims.

What is claimed is:

1. A semiconductor structure comprising:
a semiconductor substrate;
a metal layer formed on the semiconductor substrate;
a conductive pillar formed on the metal layer and electrically coupled with the metal layer, wherein the conductive pillar comprises a bearing surface and a horizontal cross-sectional surface under the bearing surface, and the contact surface area of the bearing surface is larger than the area of the horizontal cross-sectional surface; and
a solder ball placed on the conductive pillar and covering the bearing surface.

2. The semiconductor structure according to claim 1, wherein the contact surface area of the bearing surface is larger than or equal to 1.2 times the area of the horizontal cross-sectional surface.

3. The semiconductor structure according to claim 2, wherein the semiconductor structure comprises a pillar height measured from the highest point of the bearing surface to a surface of the metal layer and a lowest point height measured from the lowest point of the bearing surface to the surface of the metal layer, wherein the lowest point height is between 70% and 95% of the pillar height.

4. The semiconductor structure according to claim 3, wherein the bearing surface is a concave surface.

5. The semiconductor structure according to claim 3, wherein the bearing surface comprises at least one protrusion.

6. The semiconductor structure according to claim 5, wherein the bearing surface further comprises a first plane surrounding the protrusion, and the protrusion comprises a sidewall, wherein the angle included by the sidewall and the first plane is between 70 and 90 degrees.

7. The semiconductor structure according to claim 3, wherein the bearing surface comprises a wall and a concave region, and the wall surrounds the concave region.

8. The semiconductor structure according to claim 7, wherein the wall comprises an inner sidewall, and the angle included by the inner sidewall and a surface of the concave region is between 70 and 90 degrees.

9. The semiconductor structure according to claim 2, wherein the conductive pillar comprises a pillar height measured from the highest point of the bearing surface to a surface of the metal layer, and a distance between the highest point of the bearing surface to the lowest point of the bearing surface is between 5% and 15% of the pillar height.

10. The semiconductor structure according to claim 9, wherein the bearing surface is a concave surface.

11. The semiconductor structure according to claim 9, wherein the bearing surface comprises at least one protrusion.

12. The semiconductor structure according to claim 11, wherein the bearing surface further comprises a first plane surrounding the protrusion, and the protrusion comprises a sidewall, wherein the angle included by the sidewall and the first plane is between 70 and 90 degrees.

13. The semiconductor structure according to claim 9, wherein the bearing surface comprises a wall and a concave region, and the wall surrounds the concave region.

14. The semiconductor structure according to claim 13, wherein the wall comprises an inner sidewall, and the angle included by the inner sidewall and a surface of the concave region is between 70 and 90 degrees.

15. The semiconductor structure according to claim 1, wherein the metal layer is an under bump metallization (UBM).
